(19) United States
(12) Patent Application Publication
(10) Pub. No.: US 2025/0138348 A1
(43) Pub. Date: May 1, 2025

(54) OPTICAL ELEMENT AND LASER MODULE

(71) Applicant: TDK Corporation, Tokyo (JP)

(72) Inventors: Yasuhiro TAKAGI, Tokyo (JP); Hiroki Hara, Tokyo (JP); Atsushi Shimura, Tokyo (JP); Jiro Yoshinari, Tokyo (JP)

(73) Assignee: TDK Corporation, Tokyo (JP)

(21) Appl. No.: 18/882,916

(22) Filed: Sep. 12, 2024

(30) Foreign Application Priority Data
Oct. 27, 2023 (JP) 2023-184914

(51) Int. Cl. G02F 1/035; G02F 1/01

(52) U.S. Cl. CPC G02F 1/0353; G02F 1/0136

(57) ABSTRACT

In a first region of a first conversion portion, a length of an upper tapered portion in a third direction continuously increases from a first length at a first end to a second length toward an intermediate position, and a length of a lower tapered portion in the third direction continuously increases from the first length at the first end to a third length, which is longer than the second length, toward the intermediate position. In a second region of the first conversion portion, a length of the upper tapered portion in the third direction continuously increases from the second length at the intermediate position to a fourth length, which is shorter than the third length, toward a second end, and a length of the lower tapered portion in the third direction continuously decreases from the third length at the intermediate position to the fourth length toward the second end.

### CROSS-REFERENCE TO RELATED APPLICATIONS

This application claims the benefit of priority from Japanese Patent Application No. 2023-184914 filed with the Japan Patent Office on Oct. 27, 2023, the entire contents of which are incorporated herein by reference.

### TECHNICAL FIELD

The present disclosure relates to an optical element and a laser module.

### BACKGROUND

The polarization mode of light propagating through the optical waveguide includes a transverse electric (TE) mode, which is a polarization mode having a main electric field in a direction parallel to the substrate, and a transverse magnetic (TM) mode, which is a polarization mode having a main electric field in a direction perpendicular to the substrate. An optical waveguide element for converting these polarization modes is known. For example, Japanese Unexamined Patent Application Publication No. 2023-34349 describes an optical waveguide element including a core having a tapered shape in which the width gradually increases continuously from the input end to the output end and a groove having a V-shaped cross section formed on the upper surface.

### SUMMARY

The optical waveguide element described in Japanese Unexamined Patent Application Publication No. 2023-34349 converts TM0 mode light having a wavelength of 1550 nm into TE1 mode light. However, no consideration is given to visible light.

The present disclosure describes an optical element and a laser module capable of converting a polarization mode of visible light.

An optical element according to one aspect of the present disclosure includes: a substrate including a main surface; and a core layer provided on the main surface and made of a material having an electro-optic effect. The core layer includes a mode converter that extends in a first direction along the main surface and that converts a polarization mode of visible light between a TM0 mode and a TE0 mode. The mode converter includes: an incident portion that is positioned at one end of the mode converter in the first direction, and on which the visible light in a first polarization mode which is one polarization mode among the TM0 mode and the TE0 mode is incident; an emission portion that is positioned at another end of the mode converter in the first direction, and that emits the visible light in a second polarization mode which is another polarization mode among the TM0 mode and the TE0 mode; a first conversion portion that is provided between the incident portion and the emission portion, and that converts the polarization mode of the visible light between the TM0 mode and a TE1 mode; and a second conversion portion that is provided between the incident portion and the emission portion, and that converts the polarization mode of the visible light between the TE0 mode and the TE1 mode. The first conversion portion includes a first end and a second end which are both ends in the first direction, and an upper tapered portion and a lower tapered portion which are stacked in a second direction intersecting the main surface. In a first region of the first conversion portion from the first end to an intermediate position between the first end and the second end, a length of the upper tapered portion in a third direction intersecting the first direction and the second direction continuously increases from a first length at the first end to a second length, which is longer than the first length, toward the intermediate position. In the first region, a length of the lower tapered portion in the third direction continuously increases from the first length at the first end to a third length, which is longer than the second length, toward the intermediate position. In a second region of the first conversion portion from the intermediate position to the second end, a length of the upper tapered portion in the third direction continuously increases from the second length at the intermediate position to a fourth length, which is longer than the second length and shorter than the third length, toward the second end. In the second region, a length of the lower tapered portion in the third direction continuously decreases from the third length at the intermediate position to the fourth length toward the second end.

In the optical element, the first conversion portion converts the polarization mode of visible light between the TM0 mode and the TE1 mode. In the first conversion portion, since the upper tapered portion and the lower tapered portion are stacked in the second direction, the first conversion portion has asymmetry in the second direction. In the first conversion portion, the effective refractive indices of the TM0 mode and the TE1 mode become closer to each other as the distance from the first end increases, so that conversion between the TM0 mode and the TE1 mode is induced. For example, when the visible light in the TM0 mode is incident on the first end of the first conversion portion, the polarization mode of the visible light is converted from the TM0 mode to the TE1 mode in the first conversion portion, and then converted from the TE1 mode to the TE0 mode in the second conversion portion. Similarly, when the visible light in the TE0 mode is incident on the second conversion portion, the polarization mode of the visible light is converted from the TE0 mode to the TE1 mode in the second conversion portion, and then converted from the TE1 mode to the TM0 mode in the first conversion portion. As described above, the polarization mode of the visible light can be converted between the TM0 mode and the TE0 mode.

The first polarization mode may be the TM0 mode and the second polarization mode may be the TE0 mode. The first end may be connected to the incident portion, and the second conversion portion may be provided between the first conversion portion and the emission portion. In this case, the visible light incident in the TM0 mode can be emitted in the TE0 mode.

The first polarization mode may be the TE0 mode and the second polarization mode may be the TM0 mode. The first end may be connected to the emission portion, and the second conversion portion may be provided between the incident portion and the first conversion portion. In this case, the visible light incident in the TE0 mode can be emitted in the TM0 mode.

A length of the first conversion portion in the first direction may be 360 μm or more and 1010 μm or less. The second length may be 0.5 μm or more and 1.0 μm or less. The third length may be 1.0 μm or more and 5.0 μm or less. In this case, the loss of light intensity in the conversion between the TM0 mode and the TE1 mode can be reduced. Accordingly, the conversion efficiency between the TM0 mode and the TE1 mode can be improved.

The second conversion portion may include: a first asymmetric portion having an asymmetric shape in the third direction, with a length in the third direction continuously increasing from a fifth length to a sixth length, which is longer than the fifth length, as a distance from the first conversion portion increases; a second asymmetric portion having an asymmetric shape in the third direction, with a length in the third direction continuously decreasing from the sixth length to a seventh length, which is shorter than the sixth length, as a distance from the first conversion portion increases; and a connecting portion provided between the first asymmetric portion and the second asymmetric portion, with a length in the third direction being the sixth length over an entire length in the first direction. In this case, the second conversion portion has asymmetry in the third direction. For example, when the visible light in the TE1 mode is incident on the second conversion portion, the two components of the TE1 mode having opposite phases propagate with different effective optical path lengths, so that phase changes different from each other occur in the two components. The visible light in the TE0 mode is outputted from the second conversion portion by setting the length of the first asymmetric portion in the first direction, the length of the second asymmetric portion in the first direction, the length of the connecting portion in the first direction, the fifth length, the sixth length, and the seventh length so that the phase matching condition under which the two components are in phase is satisfied. Similarly, when the visible light in the TE0 mode is incident on the second conversion portion, the visible light in the TE1 mode is emitted from the second conversion portion. As described above, the polarization mode of the visible light can be converted between the TE0 mode and the TE1 mode.

A length of the second conversion portion in the first direction may be 40 μm or more and 100 μm or less. A length of the second conversion portion in the third direction may be 0.4 μm or more and 1.2 μm or less. In this case, the loss of the light intensity in the conversion between the TE0 mode and the TE1 mode can be reduced. Accordingly, the conversion efficiency between the TE0 mode and the TE1 mode can be improved.

The mode converter may further include a coupling portion coupling the first conversion portion and the second conversion portion. A length of the coupling portion in the third direction may be constant over an entire length of the coupling portion in the first direction. In a configuration in which the first conversion portion and the second conversion portion are coupled to each other by extending the upper tapered portion of the first conversion portion, if the length of the upper tapered portion in the third direction is too large, an unnecessary high-order mode is generated in the visible light, and the conversion efficiency is reduced. Accordingly, in this configuration, the design of the optical element is restricted, for example, by the necessity of reducing the distance between the first conversion portion and the second conversion portion. On the other hand, in the configuration in which the first conversion portion and the second conversion portion are coupled by the coupling portion having a constant length in the third direction, the distance between the first conversion portion and the second conversion portion can be adjusted to a desired length by setting the length of the coupling portion in the third direction to a length that does not cause an unnecessary high-order mode. Accordingly, the degree of freedom in designing the optical element can be improved.

The core layer may further include: a first mode converter which is the mode converter that converts a polarization mode of red light from the first polarization mode to the second polarization mode; a second mode converter which is the mode converter that converts a polarization mode of green light from the first polarization mode to the second polarization mode; a third mode converter which is the mode converter that converts a polarization mode of blue light from the first polarization mode to the second polarization mode; and a multiplexer that multiplexes the red light, the green light, and the blue light to emit laser light. In this case, the polarization modes of the red, green, and blue light are converted from the first polarization mode to the second polarization mode. By using a polarization mode with the highest multiplexing efficiency in the multiplexer, selected from the TM0 mode and the TE0 mode, as the second polarization mode, the multiplexing efficiency can be improved.

The core layer may further include: a first modulator that modulates light intensity of the red light; a second modulator that modulates light intensity of the green light; and a third modulator that modulates light intensity of the blue light. In order to output full-color laser light by multiplexing the red light, the green light, and the blue light, it is necessary to adjust the light intensity of light of each color corresponding to the color to be output. According to the above configuration, since the light intensity of the red light, the light intensity of the green light, and the light intensity of the blue light are modulated, it is possible to output full-color laser light.

A laser module according to another aspect of the present disclosure includes: the above-described optical element; a first light source that emits the red light in the first polarization mode; a second light source that emits the green light in the first polarization mode; and a third light source that emits the blue light in the first polarization mode. Since the laser module includes the above-described optical element, the polarization mode of visible light can be converted.

According to each aspect and each embodiment of the present disclosure, the polarization mode of visible light can be converted.

### BRIEF DESCRIPTION OF THE DRAWINGS

FIG. 1 is a perspective view showing an appearance of a near-eye wearable device to which a laser module according to an embodiment is applied.

FIG. 2 is a configuration diagram schematically showing the retinal projection device shown in FIG. 1.

FIG. 3 is a plan view of the laser module shown in FIG. 2.

FIG. 4 is a cross-sectional view taken along the line IV-IV of FIG. 3.

FIG. 5 is an enlarged view of a part of the mode converter shown in FIG. 3.

FIG. 6 is a cross-sectional view taken along the line VI-VI of FIG. 5.

FIG. 7 is an enlarged view of a part of the mode converter shown in FIG. 3.

FIG. 8 is an enlarged view of the modulator shown in FIG. 3.

FIG. 9 is a cross-sectional view taken along the line IX-IX of FIG. 8.

FIG. 10 is a plan view of a laser module including an optical element according to another embodiment.

FIG. 11 is a plan view of a laser module including an optical element according to still another embodiment.

FIG. 12 is a plan view of a laser module including an optical element according to still another embodiment.

### DETAILED DESCRIPTION

Hereinafter, embodiments of the present disclosure will be described in detail with reference to the drawings. In the description of the drawings, the same elements are denoted by the same reference numerals, and redundant description will be omitted. In each figure, an XYZ coordinate system may be shown. The Y-axis direction (third direction) is a direction intersecting (for example, orthogonal to) the X-axis direction (first direction) and the Z-axis direction (second direction). The Z-axis direction is a direction intersecting (for example, orthogonal to) the X-axis direction and the Y-axis direction. In the present specification, the numerical ranges indicated by “to” represent ranges that include the values described before and after “to” as the minimum and maximum values, respectively. The individually described upper and lower limit values can be combined arbitrarily.

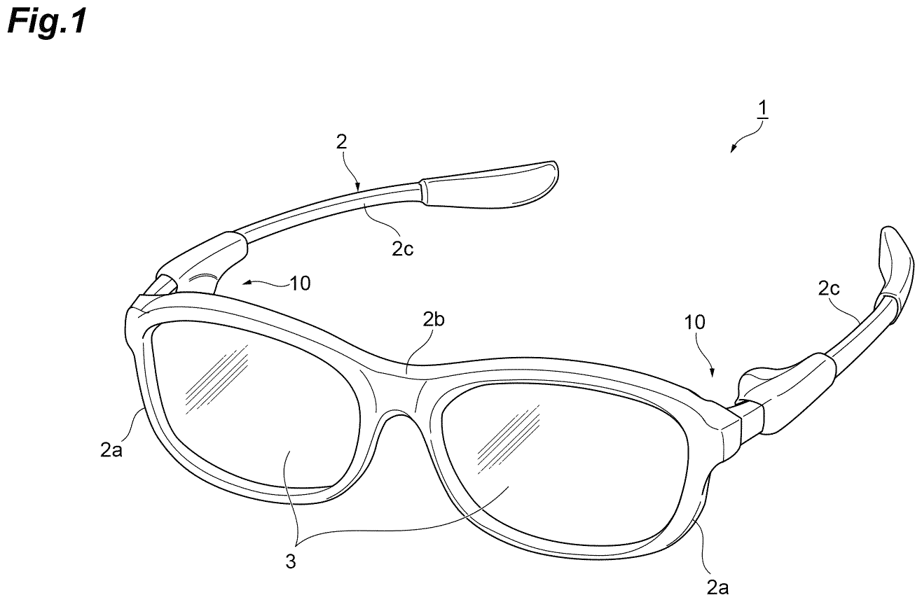

An application example of a laser module according to an embodiment will be described with reference to FIG. 1. FIG. 1 is a perspective view showing an appearance of a near-eye wearable device to which a laser module according to an embodiment is applied. The near-eye wearable device 1 shown in FIG. 1 is a device that projects images onto the retina of a user wearing the near-eye wearable device 1. The near-eye wearable device 1 is, for example, a head-mounted device, and may take the form of an eyeglass type, a goggle type, a hat type, a helmet type, or the like. Examples of the near-eye wearable device 1 include smart glasses such as augmented reality (AR) glasses, virtual reality (VR) glasses, and mixed reality (MR) glasses. The near-eye wearable device 1 includes a frame 2, a lens 3, and a retinal projection device 10.

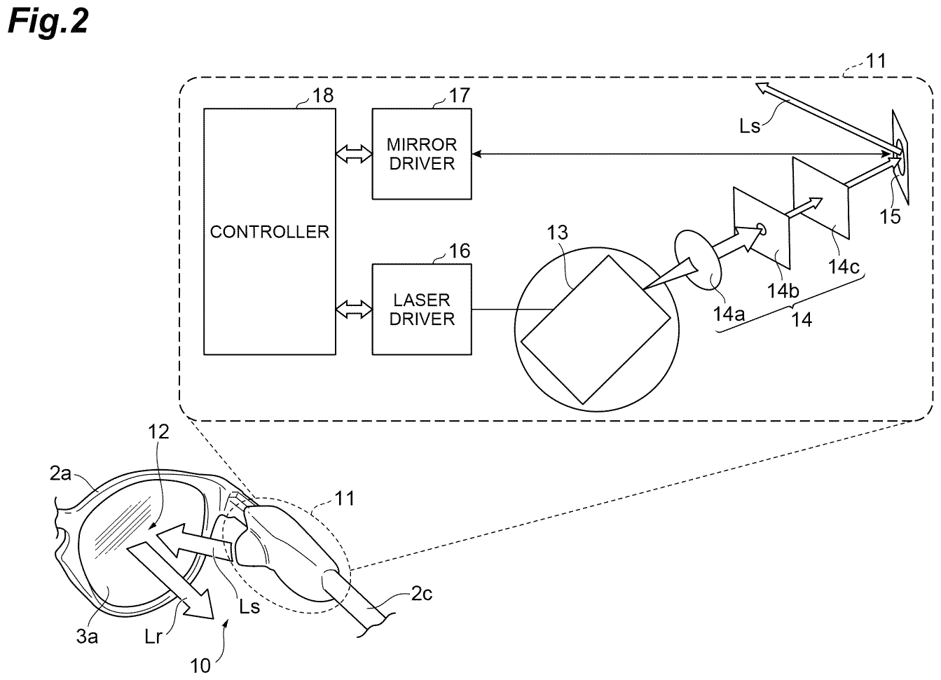

The frame 2 includes a pair of rims 2a, a bridge 2b, and a pair of temples 2c. The rim 2a is a portion for holding the lens 3. The bridge 2b is a portion connecting the pair of rims 2a. The temple 2c extends from the rim 2a and is a portion to be put on an ear of a user. The frame 2 may be a rimless frame. The lens 3 has an inner surface 3a (refer to FIG. 2) facing an eyeball of a user wearing the near-eye wearable device 1.

The retinal projection device 10 is a device for directly projecting (drawing) an image onto a retina of a user wearing the near-eye wearable device 1. The retinal projection device 10 is mounted on the near-eye wearable device 1. In the present embodiment, the near-eye wearable device 1 includes two retinal projection devices 10 in order to project an image onto both the right and left retinas, but may include only one of the retinal projection devices 10.

Next, the retinal projection device 10 will be described in detail with reference to FIG. 2. FIG. 2 is a configuration diagram schematically showing the retinal projection device shown in FIG. 1. As shown in FIG. 2, the retinal projection device 10 includes an optical engine 11 and a reflector 12.

The optical engine 11 is a device that generates laser light Ls having a color and light intensity corresponding to a pixel of an image to be projected onto the retina and emits the laser light Ls to the reflector 12. The optical engine 11 is mounted on the temple 2c. The optical engine 11 includes a laser module 13, optical components 14, a movable mirror 15, a laser driver 16, a mirror driver 17, and a controller 18.

The laser module 13 emits laser light. As the laser module 13, for example, a full-color laser module is used. The laser module 13 emits laser light having a color and light intensity corresponding to a pixel of an image to be projected onto the retina. Details of the laser module 13 will be described later.

The optical components 14 are components that optically process the laser light emitted from the laser module 13. In the present embodiment, the optical components 14 include a collimator lens 14a, a slit 14b, and a neutral density filter 14c. The collimator lens 14a, the slit 14b, and the neutral density filter 14c are arranged in this order along the optical path of the laser light. The optical components 14 may have other configurations.

The movable mirror 15 is a member for performing scanning with the laser light Ls. The movable mirror 15 is provided in a direction in which the laser light processed by the optical components 14 is emitted. The movable mirror 15 is configured to be swingable about an axis extending in the horizontal direction of the lens 3 and about an axis extending in the vertical direction of the lens 3, for example, and reflects the laser light while changing the angle in the horizontal direction and the vertical direction of the lens 3. As the movable mirror 15, for example, a micro electro mechanical systems (MEMS) mirror is used.

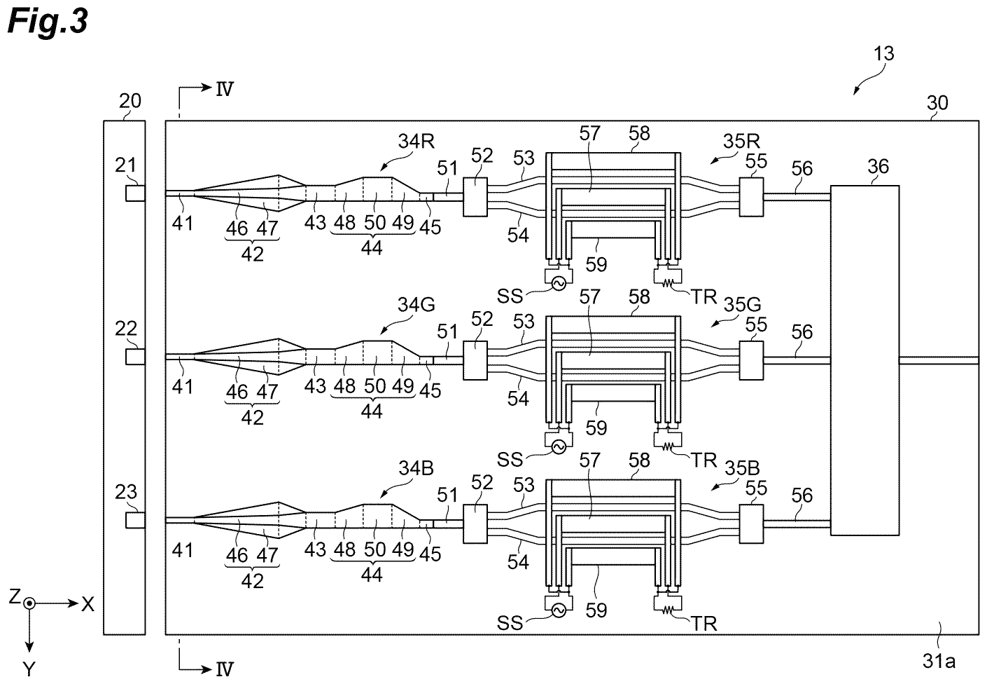

The laser driver 16 is a driving circuit for driving the laser module 13. The laser driver 16 drives the laser module 13 based on, for example, the optical power (light intensity) of the laser light and the temperature of a light source unit 20 (refer to FIG. 3) included in the laser module 13. The mirror driver 17 is a driving circuit for driving the movable mirror 15. The mirror driver 17 swings the movable mirror 15 within a predetermined angle range and at a predetermined timing. The controller 18 is a device for controlling the laser driver 16 and the mirror driver 17.

In the optical engine 11, laser light having a color and light intensity corresponding to a pixel of an image to be projected onto the retina is emitted from the laser module 13, passes through the optical components 14, and is reflected by the movable mirror 15. The laser light reflected by the movable mirror 15 is emitted to the reflector 12 as the laser light Ls.

The reflector 12 is a member that projects an image onto the retina of the user wearing the near-eye wearable device 1 by reflecting the laser light Ls having passed through the movable mirror 15 and irradiating the retina with reflected light Lr.

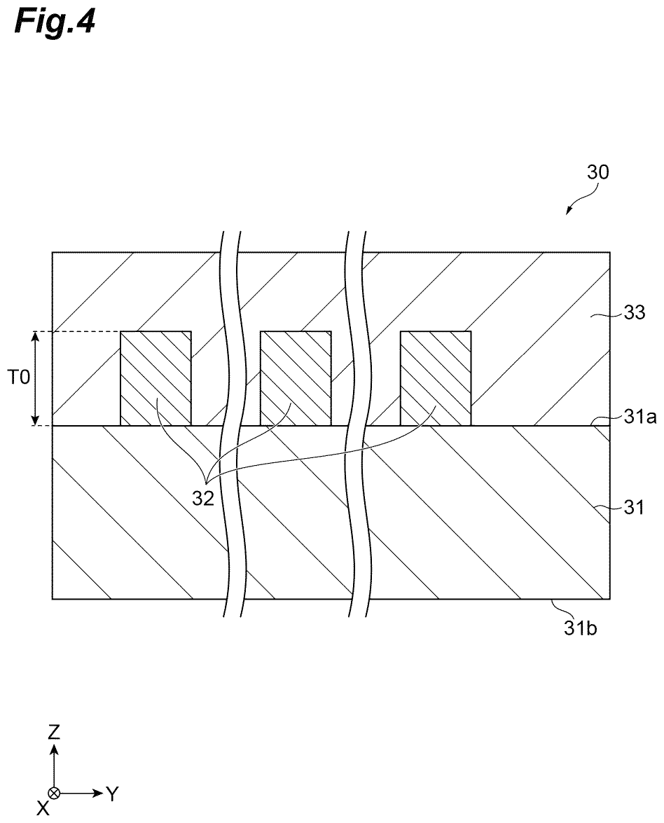

Next, the laser module 13 will be described in detail with reference to FIGS. 3 and 4. FIG. 3 is a plan view of the laser module shown in FIG. 2. FIG. 4 is a cross-sectional view taken along the line IV-IV of FIG. 3. In FIG. 3, the illustration of a cladding layer 33 is omitted for convenience of explanation. As shown in FIG. 3, the laser module 13 includes the light source unit 20 and an optical element 30.

The light source unit 20 emits visible light. The light source unit 20 includes a red laser diode 21 (first light source) for emitting red light, a green laser diode 22 (second light source) for emitting green light, and a blue laser diode 23 (third light source) for emitting blue light. The peak wavelength of the red light is, for example, in the range of 600 nm to 830 nm. The peak wavelength of the green light is, for example, in the range of 500 nm to 570 nm. The peak wavelength of the blue light is, for example, in the range of 380 nm to 490 nm. The red laser diode 21, the green laser diode 22, and the blue laser diode 23 are arranged in that order in the Y-axis direction.

In the present embodiment, the red laser diode 21 emits red light in a TM fundamental mode (hereinafter referred to as “TM0 mode”). The green laser diode 22 emits green light in the TM0 mode. The blue laser diode 23 emits blue light in the TM0 mode.

The optical element 30 multiplexes the laser lights emitted from the respective laser diodes into one laser light. The optical element 30 is, for example, a planar lightwave circuit (PLC). As shown in FIG. 4, the optical element 30 includes a substrate 31, a core layer 32, and the cladding layer 33.

The substrate 31 functions as a lower cladding layer. The substrate 31 is made of a material having a refractive index lower than that of the constituent material of the core layer 32. Examples of the constituent materials of the substrate 31 include sapphire, silicon oxide, and silicon laminated with silicon oxide. The substrate 31 includes a main surface 31a and a rear surface 31b opposite to the main surface 31a. The main surface 31a and the rear surface 31b are surfaces defined by the X-axis direction and the Y-axis direction, and intersect with the Z-axis direction (in the present embodiment, the main surface 31a and the rear surface 31b are orthogonal to the Z-axis direction). In other words, the X-axis direction and the Y-axis direction are directions along the main surface 31a.

The cladding layer 33 functions as an upper cladding layer. The cladding layer 33 covers the core layer 32 on the main surface 31a. The cladding layer 33 is provided over the entire surface of the main surface 31a. The cladding layer 33 is made of a material having a refractive index lower than that of the constituent material of the core layer 32. An example of a constituent material of the cladding layer 33 is silicon oxide (e.g., SiO₂).

The core layer 32 is provided on the main surface 31a. The core layer 32 is made of a material having an electro-optic effect. The electro-optic effect is a phenomenon in which the refractive index of a material is changed by applying an electric field to the material. An example of a constituent material of the core layer 32 is lithium niobate (LiNbO₃). In the present embodiment, the core layer 32 is made of X-cut lithium niobate, and the optical axis (C-axis) of the lithium niobate extends in the Y-axis direction. The core layer 32 includes a mode converter 34R (first mode converter), a mode converter 34G (second mode converter), a mode converter 34B (third mode converter), a modulator 35R (first modulator), a modulator 35G (second modulator), a modulator 35B (third modulator), and a multiplexer 36.

The mode converter 34R is a mode converter that converts the polarization mode of the red light between the TM0 mode and a TE fundamental mode (hereinafter referred to as “TE0 mode”). In the present embodiment, the mode converter 34R converts the polarization mode of the red light from the TM0 mode (first polarization mode) to the TE0 mode (second polarization mode). The mode converter 34G is a mode converter that converts the polarization mode of the green light between the TM0 mode and the TE0 mode. In the present embodiment, the mode converter 34G converts the polarization mode of the green light from the TM0 mode to the TE0 mode. The mode converter 34B is a mode converter that converts the polarization mode of the blue light between the TM0 mode and the TE0 mode. In the present embodiment, the mode converter 34B converts the polarization mode of the blue light from the TM0 mode to the TE0 mode.

The polarization mode is also referred to as a waveguide mode. The TM mode is a polarization mode in which the main component of the electric field in the cross section perpendicular to the light propagation direction is oriented perpendicular to the main surface 31a of the substrate 31. The TE mode is a polarization mode in which the main component of the electric field in the cross section perpendicular to the light propagation direction is oriented parallel to the main surface 31a of the substrate 31. The TM0 mode is a polarization mode having the highest effective refractive index among the TM modes. The TE0 mode is a polarization mode having the highest effective refractive index among the TE modes. The TE first-order mode (hereinafter referred to as “TE1 mode”) is a polarization mode having the second highest effective refractive index among the TE modes.

Each of the mode converter 34R, the mode converter 34G, and the mode converter 34B extends in the X-axis direction. The mode converter 34R, the mode converter 34G, and the mode converter 34B are arranged in that order in the Y-axis direction. The detailed configuration of each mode converter will be described later.

The modulator 35R is a modulator that modulates the light intensity of the red light. The modulator 35R is provided subsequent to the mode converter 34R, and modulates the light intensity of the red light in the TE0 mode emitted from the mode converter 34R. The modulator 35G is a modulator that modulates the light intensity of the green light. The modulator 35G is provided subsequent to the mode converter 34G, and modulates the light intensity of the green light in the TE0 mode emitted from the mode converter 34G. The modulator 35B is a modulator that modulates the light intensity of the blue light. The modulator 35B is provided subsequent to the mode converter 34B, and modulates the light intensity of the blue light in TE0 mode emitted from the mode converter 34B. The detailed configuration of each modulator will be described later.

The multiplexer 36 multiplexes the red light, the green light, and the blue light. The multiplexer 36 multiplexes the red light emitted from the modulator 35R, the green light emitted from the modulator 35G, and the blue light emitted from the modulator 35B into a single laser light to emit the laser light. The laser light contains a component having a red wavelength (red component), a component having a green wavelength (green component), and a component having a blue wavelength (blue component).

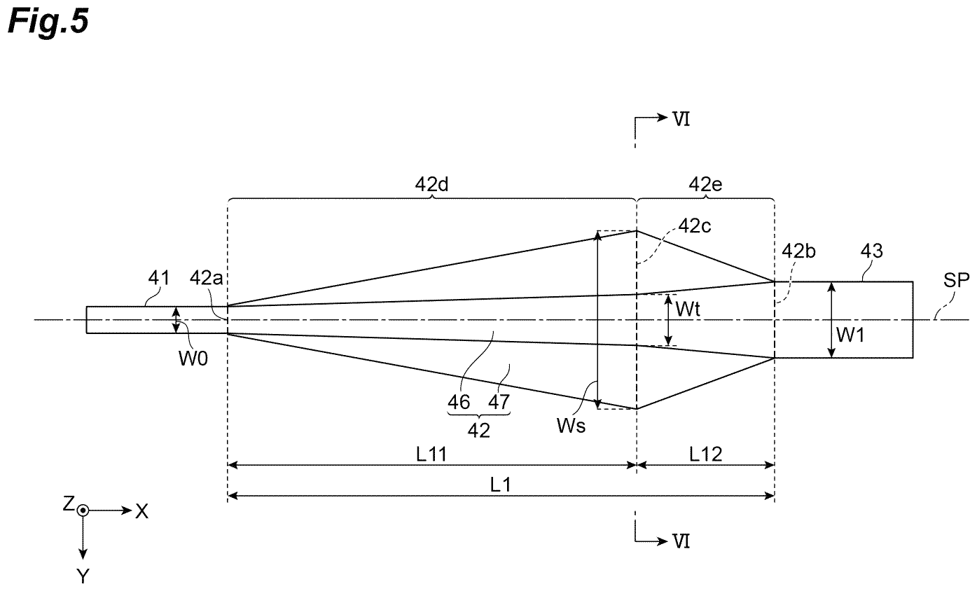

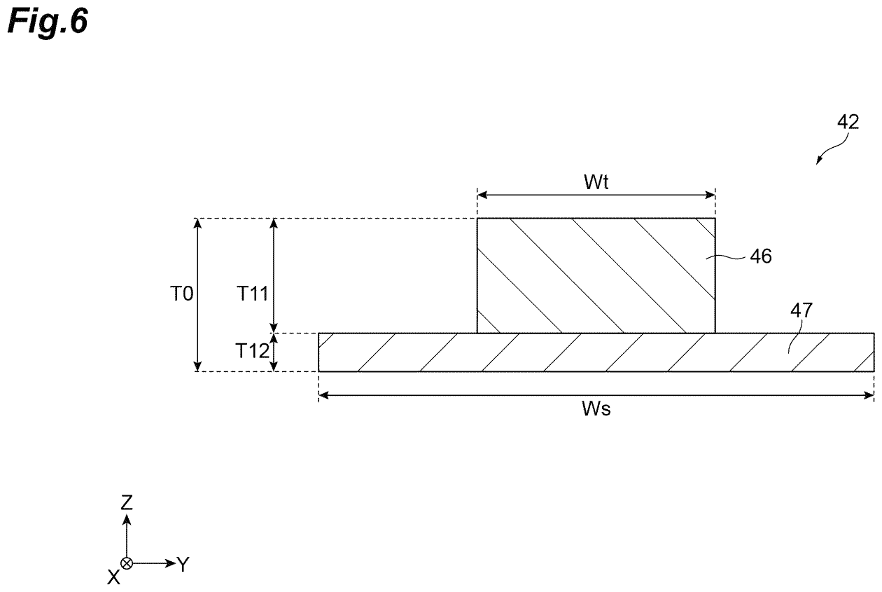

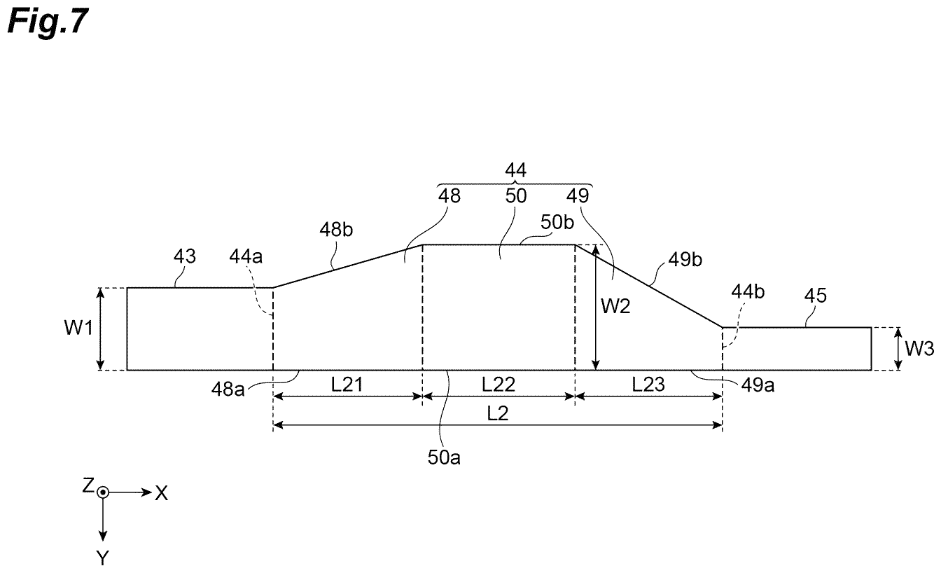

Next, the detailed configurations of the mode converters 34R, 34G, and 34B will be described with further reference to FIGS. 5 to 7. FIG. 5 is an enlarged view of a part of the mode converter shown in FIG. 3. FIG. 6 is a cross-sectional view taken along the line VI-VI of FIG. 5. FIG. 7 is an enlarged view of a part of the mode converter shown in FIG. 3. As shown in FIG. 3, each of the mode converter 34R, the mode converter 34G, and the mode converter 34B includes an end portion 41, a conversion portion 42 (first conversion portion), a coupling portion 43, a conversion portion 44 (second conversion portion), and an end portion 45. Since the mode converter 34R, the mode converter 34G, and the mode converter 34B have similar configurations, the configuration of the mode converter 34R will be described here.

As shown in FIGS. 3 and 5, the end portion 41 is an optical waveguide positioned at one end (incident end) of the mode converter 34R in the X-axis direction. The end portion 41 functions as an incident portion. The end portion 41 is provided on the main surface 31a and extends in the X-axis direction. The red light in TM0 mode is incident from the red laser diode 21 on one end of the end portion 41 in the X-axis direction. The end portion 41 transmits the red light while maintaining the polarization mode of the red light, and emits the red light in the TM0 mode to the conversion portion 42.

The cross section of the end portion 41 intersecting (orthogonal to) the X-axis direction has a rectangular shape. The cross section may have a trapezoidal shape. The length of the end portion 41 in the X-axis direction is, for example, 50 μm. The length of the end portion 41 in the Y-axis direction is substantially constant over the entire length of the end portion 41 in the X-axis direction. Hereinafter, the length in the Y-axis direction may be referred to as “width”. The width of the end portion 41 is a width W0 (first length). The width W0 is, for example, 0.45 μm. The length of the end portion 41 in the Z-axis direction is substantially constant over the entire length of the end portion 41 in the X-axis direction. Hereinafter, the length in the Z-axis direction may be referred to as “height”. The height of the end portion 41 is a height T0. The height T0 is, for example, 0.7 μm.

As shown in FIGS. 3, 5 and 6, the conversion portion 42 is provided between the end portion 41 and the end portion 45, and is a portion that converts the polarization mode of the visible light between the TM0 mode and the TE1 mode. In the present embodiment, the conversion portion 42 is provided between the end portion 41 and the coupling portion 43, and converts the polarization mode of the visible light from the TM0 mode to the TE1 mode. The conversion portion 42 is provided on the main surface 31a. The conversion portion 42 includes a connection end 42a (first end) and a connection end 42b (second end) which are both ends in the X-axis direction. The connection end 42a is connected to the other end of the end portion 41 in the X-axis direction. The connection end 42b is connected to one end of the coupling portion 43 in the X-axis direction.

The conversion portion 42 is divided into a conversion region 42d (first region) and a conversion region 42e (second region) at an intermediate position 42c. The intermediate position 42c is a position between the connection end 42a and the connection end 42b in the X-axis direction. The conversion region 42d is a region from the connection end 42a to the intermediate position 42c in the conversion portion 42. The conversion region 42e is a region from the intermediate position 42c to the connection end 42b in the conversion portion 42. The length L11 of the conversion region 42d in the X-axis direction is, for example, 350 μm to 1000 μm. The length L12 of the conversion region 42e in the X-axis direction is, for example, 10 μm to 80 μm. The length L1 of the conversion portion 42 in the X-axis direction is equal to the sum of the length L11 and the length L12, and is, for example, 360 μm to 1010 μm.

The conversion portion 42 includes an upper tapered portion 46 and a lower tapered portion 47. The upper tapered portion 46 and the lower tapered portion 47 are stacked in the Z-axis direction. Specifically, the lower tapered portion 47 is provided on the main surface 31a, and the upper tapered portion 46 is provided on the lower tapered portion 47. The height of the upper tapered portion 46 is substantially constant over the entire length of the upper tapered portion 46 in the X-axis direction. The height of the upper tapered portion 46 is a height T11. The height T11 is, for example, 0.5 μm. The height of the lower tapered portion 47 is substantially constant over the entire length of the lower tapered portion 47 in the X-axis direction. The height of the lower tapered portion 47 is a height T12. The height T12 is, for example, 0.2 μm. The height of the conversion portion 42 is equal to the sum of the height of the upper tapered portion 46 and the height of the lower tapered portion 47, and is a height T0.

In the conversion region 42d, the width of the upper tapered portion 46 continuously increases from the width W0 at the connection end 42a to the width Wt (second length) toward the intermediate position 42c. The width Wt is larger than the width W0. The width Wt is, for example, 0.5 μm to 1.0 μm. The rate of increase in the width of the upper tapered portion 46 in the conversion region 42d may be substantially constant. In the conversion region 42e, the width of the upper tapered portion 46 continuously increases from the width Wt at the intermediate position 42c to the width W1 (fourth length) toward the connection end 42b. The width W1 is larger than the width Wt and smaller than a width Ws described later. The width W1 is, for example, 0.85 μm. The rate of increase in the width of the upper tapered portion 46 in the conversion region 42e may be substantially constant. The upper tapered portion 46 has a shape symmetric with respect to a symmetry plane SP defined by the X-axis direction and the Z-axis direction.

In the conversion region 42d, the width of the lower tapered portion 47 continuously increases from the width W0 at the connection end 42a to the width Ws (third length) toward the intermediate position 42c. The width Ws is larger than the width Wt. The width Ws is, for example, 1.0 μm to 5.0 μm. The rate of increase in the width of the lower tapered portion 47 in the conversion region 42d may be substantially constant. In the conversion region 42e, the width of the lower tapered portion 47 continuously decreases from the width Ws at the intermediate position 42c to the width W1 toward the connection end 42b. The rate of decrease in the width of the lower tapered portion 47 in the conversion region 42e may be substantially constant. The lower tapered portion 47 has a shape symmetrical with respect to the symmetry plane SP.

In the conversion portion 42 configured as described above, since the upper tapered portion 46 and the lower tapered portion 47 are stacked in the Z-axis direction, the conversion portion 42 has an asymmetry in the Z-axis direction. Here, the term “asymmetry in the Z-axis direction” means that, with respect to a symmetry plane that passes through the center of the conversion portion 42 in the Z-axis direction and is orthogonal to the Z-axis direction, two portions separated by the symmetry plane are not plane-symmetric.

In the conversion portion 42, the effective refractive index of the TM0 mode and the effective refractive index of the TE1 mode approach and then intersect each other as the distance from the connection end 42a increases in the X-axis direction, so that conversion between the TM0 mode and the TE1 mode is induced. Accordingly, when the red light in the TM0 mode is incident on the connection end 42a, the polarization mode of the red light is converted from the TM0 mode to the TE1 mode in the conversion portion 42. In the conversion region 42d, the width of the lower tapered portion 47 increases more than the width of the upper tapered portion 46 as the distance from the connection end 42a increases. This configuration makes it possible to improve the conversion efficiency while reducing the length of the conversion portion 42 in the X-axis direction. In the conversion region 42e, the width of the lower tapered portion 47 decreases as approaching the connection end 42b, and the width of the upper tapered portion 46 and the width of the lower tapered portion 47 become equal at the connection end 42b. This configuration makes it possible to further improve the conversion efficiency.

For example, about 50% to 60% of the conversion from the TM0 mode to the TE1 mode is performed in the conversion region 42d, and about 20% to 30% of the conversion from the TM0 mode to the TE1 mode is performed in the conversion region 42e. On the other hand, the effective refractive index of the TE0 mode is sufficiently far from the effective refractive indices of the TM0 mode and the TE1 mode over the entire length of the conversion portion 42 in the X-axis direction. Accordingly, when the red light in the TE0 mode is incident on the connection end 42a, the polarization mode of the red light is maintained in the TE0 mode.

As shown in FIGS. 3 and 5, the coupling portion 43 is an optical waveguide for coupling the conversion portion 42 and the conversion portion 44. The coupling portion 43 is provided on the main surface 31a and extends in the X-axis direction. One end of the coupling portion 43 in the X-axis direction is connected to the connection end 42b, and the other end of the coupling portion 43 in the X-axis direction is connected to the conversion portion 44. The red light in the TE1 mode is incident on the coupling portion 43 from the conversion portion 42. The coupling portion 43 transmits the red light while maintaining the polarization mode of the red light, and emits the red light in the TE1 mode to the conversion portion 44.

The cross section of the coupling portion 43 intersecting (orthogonal to) the X-axis direction has a rectangular shape. The cross section may have a trapezoidal shape. The length of the coupling portion 43 in the X-axis direction is, for example, 50 μm. The width of the coupling portion 43 is substantially constant over the entire length of the coupling portion 43 in the X-axis direction. The width of the coupling portion 43 is the width W1. The height of the coupling portion 43 is substantially constant over the entire length of the coupling portion 43 in the X-axis direction. The height of the coupling portion 43 is the height T0.

As shown in FIGS. 3 and 7, the conversion portion 44 is provided between the end portion 41 and the end portion 45, and is a portion that converts the polarization mode of the visible light between the TE0 mode and the TE1 mode. In the present embodiment, the conversion portion 44 is provided between the coupling portion 43 and the end portion 45, and converts the polarization mode of the visible light from the TE1 mode to the TE0 mode. The conversion portion 44 is provided on the main surface 31a. The conversion portion 44 includes a connection end 44a and a connection end 44b which are both ends in the X-axis direction. The connection end 44a is connected to the other end of the coupling portion 43 in the X-axis direction. The connection end 44b is connected to one end of the end portion 45 in the X-axis direction. The conversion portion 44 includes an asymmetric portion 48 (first asymmetric portion), an asymmetric portion 49 (second asymmetric portion), and a connecting portion 50.

The asymmetric portion 48 is an optical waveguide having an asymmetric shape in the Y-axis direction when viewed from the Z-axis direction (in plan view). The asymmetric portion 48 includes the connection end 44a. The width of the asymmetric portion 48 continuously increases from the width W1 (fifth length) at the connection end 44a to the width W2 (sixth length) as approaching the connection end 44b. In other words, the width of the asymmetric portion 48 continuously increases from the width W1 to the width W2 as the distance from the coupling portion 43 increases. The width W2 is larger than the width W1. The width W2 is, for example, 1.2 μm. The rate of increase in the width of the asymmetric portion 48 may be substantially constant. The height of the asymmetric portion 48 is substantially constant over the entire length of the asymmetric portion 48 in the X-axis direction. The height of the asymmetric portion 48 is the height T0. The length L21 of the asymmetric portion 48 in the X-axis direction is, for example, 13 μm to 37 μm.

The asymmetric portion 48 includes side surfaces 48a and 48b which are both side surfaces in the Y-axis direction. The side surface 48a extends in the X-axis direction. The side surface 48b is inclined so as to be separated from the side surface 48a as the distance from the coupling portion 43 increases.

The asymmetric portion 49 is an optical waveguide having an asymmetric shape in the Y-axis direction when viewed from the Z-axis direction (in plan view). The asymmetric portion 49 includes the connection end 44b. The width of the asymmetric portion 49 continuously decreases from the width W2 to the width W3 (seventh length) as the distance from the coupling portion 43 increases. The width W3 is smaller than the width W2. The width W3 is, for example, 0.4 μm. The rate of decrease in the width of the asymmetric portion 49 may be substantially constant. The height of the asymmetric portion 49 is substantially constant over the entire length of the asymmetric portion 49 in the X-axis direction. The height of the asymmetric portion 49 is the height T0. The length L23 of the asymmetric portion 49 in the X-axis direction is, for example, 13 μm to 37 μm.

The asymmetric portion 49 includes side surfaces 49a and 49b which are both side surfaces in the Y-axis direction. The side surface 49a extends in the X-axis direction. The side surface 49b is inclined so as to approach the side surface 49a as the distance from the coupling portion 43 increases.

The connecting portion 50 is provided between the asymmetric portion 48 and the asymmetric portion 49 and is an optical waveguide for connecting the asymmetric portion 48 and the asymmetric portion 49. The width of the connecting portion 50 is substantially constant over the entire length of the connecting portion 50 in the X-axis direction. The width of the connecting portion 50 is the width W2. The height of the connecting portion 50 is substantially constant over the entire length of the connecting portion 50 in the X-axis direction. The height of the connecting portion 50 is the height T0. The length L22 of the connecting portion 50 in the X-axis direction is, for example, 14 μm to 26 μm. The connecting portion 50 includes side surfaces 50a and 50b which are both side surfaces in the Y-axis direction. The side surfaces 50a and 50b extend in the X-axis direction and are substantially parallel to each other. The side surfaces 48a, 50a, and 49a are located on the same plane.

The length L2 of the conversion portion 44 in the X-axis direction is equal to the sum of the length L21, the length L22, and the length L23, and is, for example, 40 μm to 100 μm. The width of the conversion portion 44 is, for example, 0.4 μm to 1.2 μm.

In the conversion portion 44 configured as described above, the asymmetric portion 48, the connecting portion 50, and the asymmetric portion 49 are arranged in that order in the X-axis direction, so that the conversion portion 44 has asymmetry in the Y-axis direction. Here, the term “asymmetry in the Y-axis direction” means that, with respect to a symmetry plane that passes through the center of the conversion portion 44 in the Y-axis direction and is orthogonal to the Y-axis direction, two portions separated by the symmetry plane are not plane-symmetric. When the red light in the TE1 mode is incident on the connection end 44a, the two components of the TE1 mode having phases opposite to each other are propagated with effective optical path lengths different from each other, so that phase changes different from each other occur in the two components. Since the width W1, the width W2, the width W3, the length L21, the length L22, and the length L23 are set so that the phase matching condition under which the two components are in phase is satisfied, the red light in the TE0 mode is output from the connection end 44b.

As shown in FIGS. 3 and 7, the end portion 45 is an optical waveguide positioned at the other end (emission end) of the mode converter 34R in the X-axis direction. The end portion 45 functions as an emission portion. The end portion 45 is provided on the main surface 31a and extends in the X-axis direction. One end of the end portion 45 in the X-axis direction is connected to the connection end 44b, and the other end of the end portion 45 in the X-axis direction is connected to the modulator 35R. The red light in the TE0 mode is incident on one end of the end portion 45 in the X-axis direction from the conversion portion 44. The end portion 45 transmits the red light while maintaining the polarization mode of the red light, and emits the red light in the TE0 mode to the modulator 35R.

The cross section of the end portion 45 intersecting (orthogonal to) the X-axis direction has a rectangular shape. The cross section may have a trapezoidal shape. The length of the end portion 45 in the X-axis direction is, for example, 50 μm. The width of the end portion 45 is substantially constant over the entire length of the end portion 45 in the X-axis direction. The width of the end portion 45 is the width W3. The height of the end portion 45 is substantially constant over the entire length of the end portion 45 in the X-axis direction. The height of the end portion 45 is the height T0.

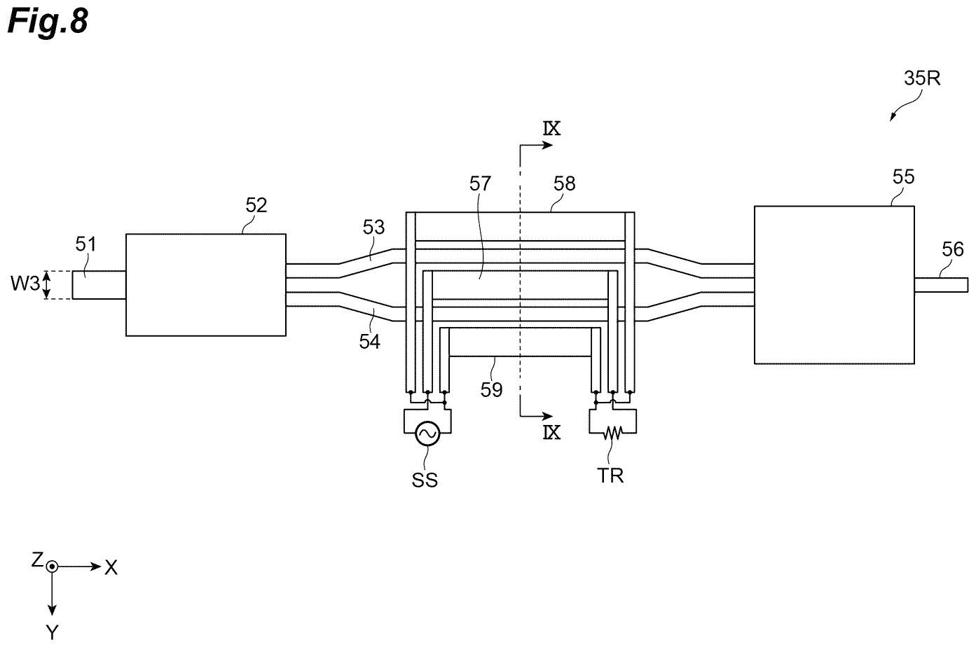

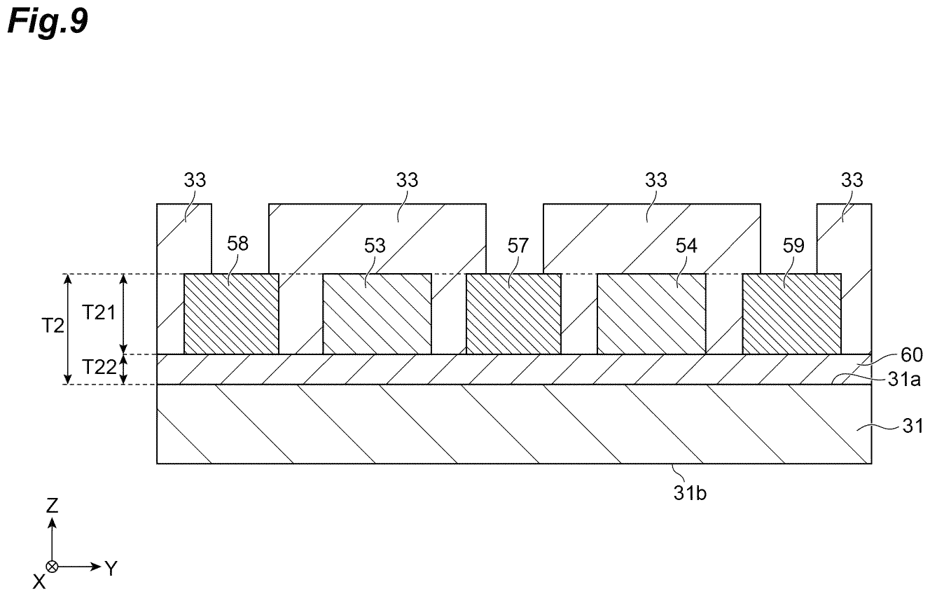

Next, the detailed configurations of the modulators 35R, 35G, and 35B will be described with reference to FIGS. 3, 8, and 9. FIG. 8 is an enlarged view of the modulator shown in FIG. 3. FIG. 9 is a cross-sectional view taken along the line IX-IX of FIG. 8. As shown in FIG. 3, each of the modulators 35R, 35G, and 35B is a Mach-Zehnder type optical waveguide and includes an input waveguide 51, a splitting portion 52, a branch waveguide 53, a branch waveguide 54, a coupling portion 55, an output waveguide 56, a signal electrode 57, a ground electrode 58, a ground electrode 59, a slab 60 (refer to FIG. 9), a signal source SS, and a termination resistor TR. Since the modulators 35R, 35G, and 35B have similar configurations, the configuration of the modulators 35R will be described here.

As shown in FIG. 9, the slab 60 is provided on the main surface 31a. The slab 60 has a flat plate shape. The height of the slab 60 is a height T22. The height T22 is, for example, 0.2 μm.

The input waveguide 51 is an optical waveguide positioned at one end (incident end) of the modulator 35R in the X-axis direction. The input waveguide 51 is provided on the slab 60 and extends in the X-axis direction. One end of the input waveguide 51 in the X-axis direction is connected to the other end of the end portion 45 in the X-axis direction. The other end of the input waveguide 51 in the X-axis direction is connected to the splitting portion 52.

The cross section of the input waveguide 51 intersecting (orthogonal to) the X-axis direction has a rectangular shape. The cross section may have a trapezoidal shape. The width of the input waveguide 51 is substantially constant over the entire length of the input waveguide 51 in the X-axis direction. The width of the input waveguide 51 is the width W3. The height of the input waveguide 51 is substantially constant over the entire length of the input waveguide 51 in the X-axis direction. The height of the input waveguide 51 is a height T21. The height T21 is, for example, 0.5 μm.

The splitting portion 52 splits the red light incident from the input waveguide 51 into two red lights. In the present embodiment, the splitting portion 52 is composed of a multimode interferometer (MMI). The splitting portion 52 may be composed of a Y-branch waveguide or may be composed of a directional coupler. The splitting portion 52 emits the two split red lights to the branch waveguides 53 and 54, respectively. The splitting portion 52 is provided on the slab 60.

The cross section of the splitting portion 52 intersecting (orthogonal to) the X-axis direction has a rectangular shape. The cross section may have a trapezoidal shape. The splitting portion 52 has a rectangular shape when viewed from the Z-axis direction. The length of the splitting portion 52 in the X-axis direction is, for example, 140 μm. The width of the splitting portion 52 is substantially constant over the entire length of the splitting portion 52 in the X-axis direction. The width of the splitting portion 52 is, for example, 10 μm. The height of the splitting portion 52 is substantially constant over the entire length of the splitting portion 52 in the X-axis direction. The height of the splitting portion 52 is the height T21.

The branch waveguide 53 is an optical waveguide through which one of the red lights split by the splitting portion 52 propagates. The branch waveguide 54 is an optical waveguide through which the other of the red lights split by the splitting portion 52 propagates. Each of the branch waveguides 53 and 54 extends in the X-axis direction from the splitting portion 52 to the coupling portion 55. The branch waveguides 53 and 54 are provided on the slab 60 and are arranged in the Y-axis direction. The branch waveguides 53 and 54 extend in the vicinity of the splitting portion 52 so as to be separated from each other in the Y-axis direction as the distance from the splitting portion 52 increases, and extend in the vicinity of the coupling portion 55 so as to be closer to each other in the Y-axis direction as the distance to the coupling portion 55 decreases. The branch waveguides 53 and 54 extend substantially in parallel between the vicinity of the splitting portion 52 and the vicinity of the coupling portion 55.

The cross section of each of the branch waveguides 53 and 54 intersecting (orthogonal to) the X-axis direction has a rectangular shape. The cross section may have a trapezoidal shape. The length of the branch waveguide 53 in the X-axis direction is, for example, 11 mm. The width of the branch waveguide 53 is substantially constant over the entire length of the branch waveguide 53. The width of the branch waveguide 53 is, for example, 0.7 μm. The height of the branch waveguide 53 is substantially constant over the entire length of the branch waveguide 53. The height of the branch waveguide 53 is the height T21. The length of the branch waveguide 54 in the X-axis direction is substantially the same as the length of the branch waveguide 53 in the X-axis direction. The width of the branch waveguide 54 is substantially the same as the width of the branch waveguide 53 and is substantially constant over the entire length of the branch waveguide 54. The height of the branch waveguide 54 is substantially the same as the height of the branch waveguide 53 and is substantially constant over the entire length of the branch waveguide 54. The coupling portion 55 couples the red light incident from the branch waveguide 53 and the red light incident from the branch waveguide 54. In the present embodiment, the coupling portion 55 is composed of an MMI. The coupling portion 55 may be composed of a Y-branch waveguide or may be composed of a directional coupler. The coupling portion 55 emits the coupled red light to the output waveguide 56. The coupling portion 55 is provided on the slab 60.

The cross section of the coupling portion 55 intersecting (orthogonal to) the X-axis direction has a rectangular shape. The cross section may have a trapezoidal shape. The coupling portion 55 has a rectangular shape when viewed from the Z-axis direction. The length of the coupling portion 55 in the X-axis direction is, for example, 140 μm. The width of the coupling portion 55 is substantially constant over the entire length of the coupling portion 55 in the X-axis direction. The width of the coupling portion 55 is, for example, 10 μm. The height of the coupling portion 55 is substantially constant over the entire length of the coupling portion 55 in the X-axis direction. The height of the coupling portion 55 is the height T21.

The output waveguide 56 is an optical waveguide positioned at the other end (emission end) of the modulator 35R in the X-axis direction. The output waveguide 56 is provided on the slab 60 and extends in the X-axis direction. One end of the output waveguide 56 in the X-axis direction is connected to the emission end of the coupling portion 55. The other end of the output waveguide 56 in the X-axis direction is connected to the incident end of the multiplexer 36.

The cross section of the output waveguide 56 intersecting (orthogonal to) the X-axis direction has a rectangular shape. The cross section may have a trapezoidal shape. The width of the output waveguide 56 is substantially constant over the entire length of the output waveguide 56 in the X-axis direction. The width of the output waveguide 56 is substantially the same as the width of the branch waveguide 53. The height of the output waveguide 56 is substantially constant over the entire length of the output waveguide 56 in the X-axis direction. The height of the output waveguide 56 is the height T21.

The signal electrode 57, the ground electrode 58, and the ground electrode 59 are provided on the slab 60 and extend in the X-axis direction. The signal electrode 57 is disposed between the branch waveguides 53 and 54. The ground electrodes 58 and 59 are arranged so as to sandwich the branch waveguides 53 and 54 in the Y-axis direction. In other words, the ground electrode 58, the branch waveguide 53, the signal electrode 57, the branch waveguide 54, and the ground electrode 59 are arranged in this order in the Y-axis direction at substantially equal intervals. The cladding layer 33 does not cover a part of the signal electrode 57, a part of the ground electrode 58, and a part of the ground electrode 59, and a part of the upper surface of the signal electrode 57, a part of the upper surface of the ground electrode 58, and a part of the upper surface of the ground electrode 59 are exposed.

The cross section of each of the signal electrode 57, the ground electrode 58, and the ground electrode 59 intersecting (orthogonal to) the X-axis direction has a rectangular shape. The length of the signal electrode 57 in the X-axis direction is, for example, 10 mm. The width of the signal electrode 57 is substantially constant over the entire length of the signal electrode 57 in the X-axis direction. The width of the signal electrode 57 is, for example, 5 μm. The height of the signal electrode 57 is substantially constant over the entire length of the signal electrode 57 in the X-axis direction. The height of the signal electrode 57 is the height T21.

The length of the ground electrode 58 in the X-axis direction is, for example, 10 mm. The width of the ground electrode 58 is substantially constant over the entire length of the ground electrode 58 in the X-axis direction. The width of the ground electrode 58 is, for example, 200 μm. The height of the ground electrode 58 is substantially constant over the entire length of the ground electrode 58. The height of the ground electrode 58 is the height T21. The length of the ground electrode 59 in the X-axis direction is substantially the same as the length of the ground electrode 58 in the X-axis direction. The width of the ground electrode 59 is substantially the same as the width of the ground electrode 58, and is substantially constant over the entire length of the ground electrode 59 in the X-axis direction. The height of the ground electrode 59 is substantially the same as the height of the ground electrode 58 and is substantially constant over the entire length of the ground electrode 59.

The signal source SS supplies a modulation signal for modulating the red light propagating through the modulator 35R. One end of the signal source SS is electrically connected to one end of the signal electrode 57, and the other end of the signal source SS is electrically connected to one end of the ground electrode 58 and one end of the ground electrode 59.

The termination resistor TR electrically terminates the modulation signal. One end of the termination resistor TR is electrically connected to the other end of the signal electrode 57, and the other end of the termination resistor TR is electrically connected to the other end of the ground electrode 58 and the other end of the ground electrode 59.

In the modulator 35R configured as described above, when the red light in the TE0 mode is incident on the input waveguide 51, the red light is split into two in-phase red lights in the TE0 mode by the splitting portion 52, and the two red lights are emitted into and propagate through the branch waveguides 53 and 54, respectively. When the modulation signal is output from the signal source SS to the signal electrode 57, the ground electrode 58, and the ground electrode 59, a potential difference corresponding to the modulation signal is generated between the signal electrode 57 and the ground electrode 58 and between the signal electrode 57 and the ground electrode 59, and a voltage in the Y-axis direction is applied to the branch waveguides 53 and 54. Accordingly, a phase difference is generated between the red light propagating through the branch waveguide 53 and the red light propagating through the branch waveguide 54.

Then, the red light propagated through the branch waveguide 53 and the red light propagated through the branch waveguide 54 are coupled at the coupling portion 55. At this time, the light intensity of the coupled red light varies in accordance with the phase difference between the red light propagated through the branch waveguide 53 and the red light propagated through the branch waveguide 54. Then, the coupled red light is emitted to the multiplexer 36 through the output waveguide 56.

In the laser module 13 and the optical element 30 described above, the conversion portion 42 converts the polarization mode of the visible light between the TM0 mode and the TE1 mode. In the conversion portion 42, the upper tapered portion 46 and the lower tapered portion 47 are stacked in the Z-axis direction, and the conversion portion 42 is asymmetric in the Z-axis direction. In the conversion portion 42, as the distance from the connection end 42a increases, the effective refractive index of the TM0 mode and the effective refractive index of the TE1 mode become closer to each other, so that conversion between the TM0 mode and the TE1 mode is induced. Accordingly, when the visible light in the TM0 mode is incident on the connection end 42a of the conversion portion 42, the polarization mode of the visible light is converted from the TM0 mode to the TE1 mode in the conversion portion 42, and then converted from the TE1 mode to the TE0 mode in the conversion portion 44. Accordingly, the visible light incident in the TM0 mode can be emitted in the TE0 mode. As described above, the polarization mode of the visible light can be converted from the TM0 mode to the TE0 mode. The length L1 may be 360 μm or more and 1010 μm or less. The width Wt may be 0.5 μm or more and 1.0 μm or less. The width Ws may be 1.0 μm or more and 5.0 μm or less. In this case, the loss of light intensity in the conversion between the TM0 mode and the TE1 mode can be reduced. Accordingly, the conversion efficiency between the TM0 mode and the TE1 mode can be improved.

The conversion portion 44 has asymmetry in the Y-axis direction. When the visible light in the TE1 mode is incident on the connection end 44a of the conversion portion 44, the two components in the TE1 mode, which are in opposite phases to each other, propagate with different effective optical path lengths. For this reason, phase changes different from each other occur in these two components. The width W1, the width W2, the width W3, the length L21, the length L22, and the length L23 are set so that the phase matching condition under which these two components are in phase is satisfied. Accordingly, the visible light in the TE0 mode is output from the connection end 44b of the conversion portion 44. As described above, the polarization mode of the visible light can be converted from the TE1 mode to the TE0 mode.

The length L2 may be 40 μm or more and 100 μm or less. The width of the conversion portion 44 may be 0.4 μm or more and 1.2 μm or less. In this case, the loss of the light intensity in the conversion between the TE0 mode and the TE1 mode can be reduced. Accordingly, the conversion efficiency between the TE0 mode and the TE1 mode can be improved.

By extending the upper tapered portion 46 of the conversion portion 42, the conversion portion 42 and the conversion portion 44 can be coupled without using the coupling portion 43. In this configuration, if the width of the upper tapered portion 46 is too wide, an unnecessary high-order mode is generated in the visible light, and the conversion efficiency is reduced. Accordingly, in this configuration, the design of the optical element 30 is restricted, for example, by the necessity of reducing the distance between the conversion portion 42 and the conversion portion 44. On the other hand, in the laser module 13 and the optical element 30, the conversion portion 42 and the conversion portion 44 are coupled to each other by the coupling portion 43, and the width of the coupling portion 43 is constant over the entire length of the coupling portion 43 in the X-axis direction. Accordingly, the distance between the conversion portion 42 and the conversion portion 44 can be adjusted to a desired length by setting the width (width W1) of the coupling portion 43 to a width that does not cause an unnecessary high-order mode. Accordingly, the degree of freedom in designing the optical element 30 can be improved.

It is known that the electro-optical characteristics of a device made of a material having an electro-optic effect, such as lithium niobate, depend on the application direction of a voltage and the polarization direction of light. For example, a large electro-optic effect can be obtained when a voltage is applied in the C-axis direction of a material having an electro-optic effect and the direction of the main electric field of light propagating through the device aligns with the C-axis direction. In the laser module 13 and the optical element 30, the core layer 32 is made of X-cut lithium niobate, and the C-axis of the lithium niobate extends in the Y-axis direction.

On the other hand, since the red laser diode 21 emits the red light in the TM0 mode, the green laser diode 22 emits the green light in the TM0 mode, and the blue laser diode 23 emits the blue light in the TM0 mode, the direction of the main electric field of each light is orthogonal to the C-axis direction of the lithium niobate constituting the core layer 32. The mode converters 34R, 34G, and 34B convert the polarization modes of the red, green, and blue light from the TM0 mode to the TE0 mode, respectively. Accordingly, the directions of the main electric fields of the respective lights are aligned with the C-axis direction, so that the modulation efficiencies in the modulators 35R, 35G, and 35B can be improved.

The core layer 32 is made of X-cut lithium niobate, and the C-axis of the lithium niobate extends in the Y-axis direction. Therefore, the multiplexer 36 is designed so that the multiplexing efficiency in the case of multiplexing the red light, the green light, and the blue light in the TE0 mode is higher than the multiplexing efficiency in the case of multiplexing the red light, the green light, and the blue light in the TM0 mode. In the laser module 13 and the optical element 30, the mode converter 34R converts the polarization mode of the red light from the TM0 mode to the TE0 mode, the mode converter 34G converts the polarization mode of the green light from the TM0 mode to the TE0 mode, and the mode converter 34B converts the polarization mode of the blue light from the TM0 mode to the TE0 mode. Accordingly, the multiplexing efficiency in the multiplexer 36 can be improved.

In order to output full-color laser light by multiplexing the red light, the green light, and the blue light, it is necessary to adjust the light intensity of light of each color corresponding to the output color. In order to change the light intensity of each color light in the light source unit 20, a large drive current is required. In the laser module 13 and the optical element 30, the light intensity of the red light is modulated by the modulator 35R, the light intensity of the green light is modulated by the modulator 35G, and the light intensity of the blue light is modulated by the modulator 35B. Accordingly, full-color laser light can be output without requiring a large drive current.

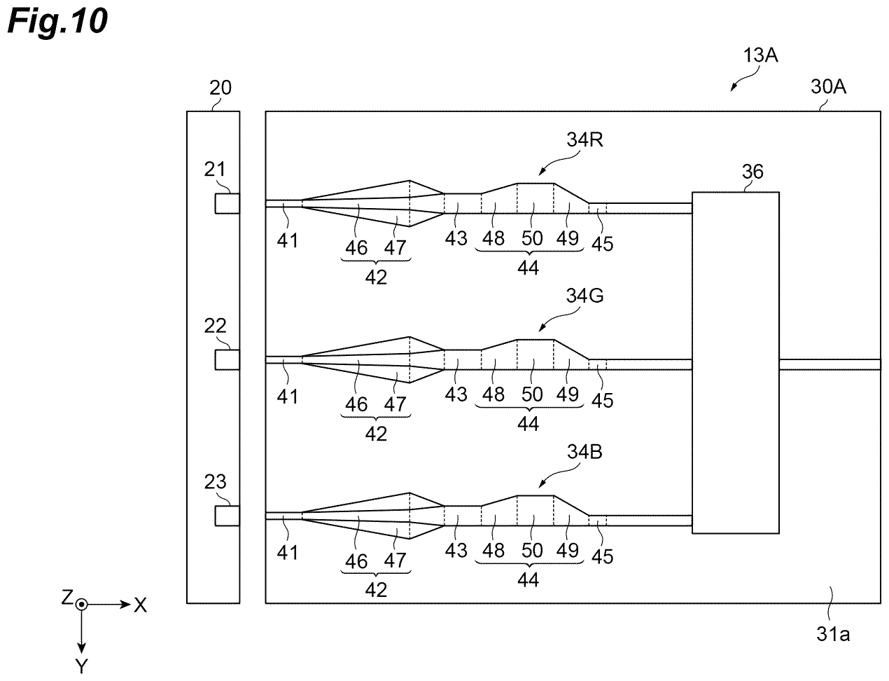

Next, a laser module including an optical element according to another embodiment will be described with reference to FIG. 10. FIG. 10 is a plan view of a laser module including an optical element according to another embodiment. In FIG. 10, the illustration of the cladding layer 33 is omitted for convenience of explanation. A laser module 13A shown in FIG. 10 is mainly different from the laser module 13 in that the laser module 13A includes an optical element 30A instead of the optical element 30. The optical element 30A is mainly different from the optical element 30 in that the optical element 30A does not include the modulators 35R, 35G, and 35B.

Also, in the laser module 13A, the same effects as those of the laser module 13 can be obtained in the configuration common to the laser module 13. Also, in the optical element 30A, the same effects as those of the optical element 30 can be obtained in the configuration common to the optical element 30. Since the laser module 13A and the optical element 30A do not include the modulators 35R, 35G, and 35B, the laser module 13A and the optical element 30A can be reduced in size.

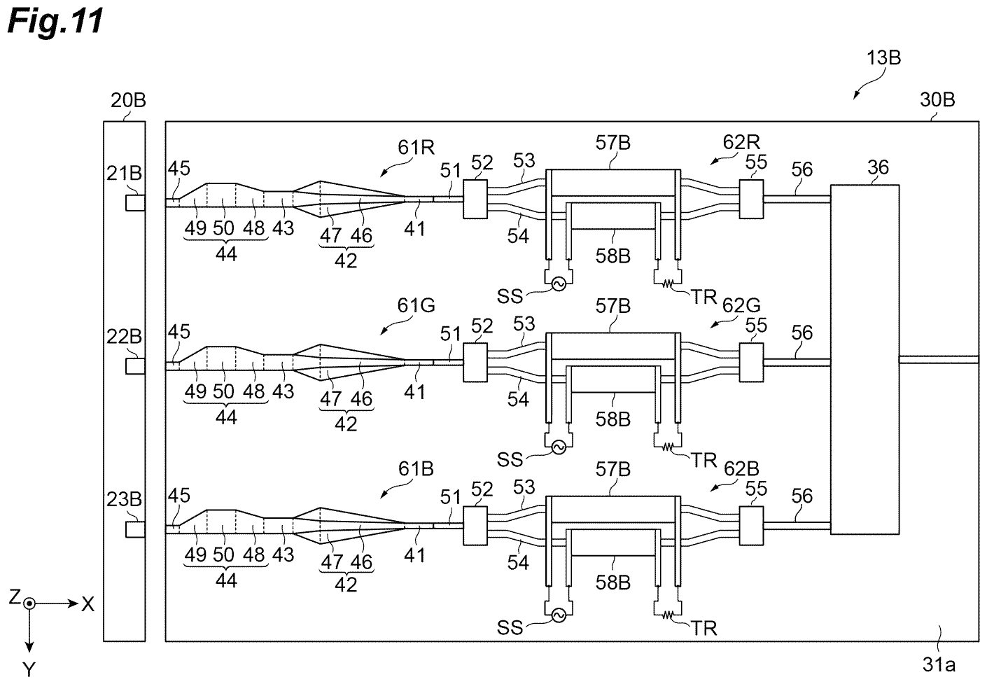

Next, a laser module including an optical element according to still another embodiment will be described with reference to FIG. 11. FIG. 11 is a plan view of a laser module including an optical element according to still another embodiment. In FIG. 11, the illustration of the cladding layer 33 is omitted for convenience of explanation. A laser module 13B shown in FIG. 11 is mainly different from the laser module 13 in that the laser module 13B includes a light source unit 20B and an optical element 30B instead of the light source unit 20 and the optical element 30.

The light source unit 20B is mainly different from the light source unit 20 in that the light source unit 20B includes a red laser diode 21B, a green laser diode 22B, and a blue laser diode 23B instead of the red laser diode 21, the green laser diode 22, and the blue laser diode 23. The red laser diode 21B is mainly different from the red laser diode 21 in the polarization mode of the emitted red light. The red laser diode 21B emits red light in the TE0 mode. The green laser diode 22B is mainly different from the green laser diode 22 in the polarization mode of the emitted green light. The green laser diode 22B emits green light in the TE0 mode. The blue laser diode 23B is mainly different from the blue laser diode 23 in the polarization mode of the emitted blue light. The blue laser diode 23B emits blue light in the TE0 mode.

The optical element 30B is mainly different from the optical element 30 in the constituent material of the core layer 32 and that the optical element 30B includes mode converters 61R, 61G, and 61B and modulators 62R, 62G, and 62B instead of the mode converters 34R, 34G, and 34B and the modulators 35R, 35G, and 35B. In the present embodiment, the core layer 32 is made of Z-cut lithium niobate, and the C-axis of the lithium niobate extends in the Z-axis direction.

The mode converter 61R (first mode converter) converts the polarization mode of the red light from the TE0 mode (first polarization mode) to the TM0 mode (second polarization mode). The mode converter 61G (second mode converter) converts the polarization mode of the green light from the TE0 mode to the TM0 mode. The mode converter 61B (third mode converter) converts the polarization mode of the blue light from the TE0 mode to the TM0 mode. Each of the mode converter 61R, the mode converter 61G, and the mode converter 61B extends in the X-axis direction. The mode converter 61R, the mode converter 61G, and the mode converter 61B are arranged in that order in the Y-axis direction.

Each of the mode converter 61R, the mode converter 61G, and the mode converter 61B includes an end portion 41, a conversion portion 42, a coupling portion 43, a conversion portion 44, and an end portion 45. Since the mode converter 61R, the mode converter 61G, and the mode converter 61B have similar configurations, the configuration of the mode converter 61R will be described here. In the mode converter 61R, the end portion 45, the conversion portion 44, the coupling portion 43, the conversion portion 42, and the end portion 41 are arranged in that order in the traveling direction of the red light. That is, the mode converter 61R has a configuration in which the mode converter 34R is inverted in the X-axis direction.

The end portion 45 is positioned at one end (incident end) of the mode converter 61R in the X-axis direction and functions as an incident portion. The red light in the TE0 mode is incident on one end of the end portion 45 in the X-axis direction from the red laser diode 21B. The end portion 45 transmits the red light while maintaining the polarization mode of the red light, and emits the red light in the TE0 mode to the conversion portion 44.

The conversion portion 44 is provided between the end portion 45 and the coupling portion 43, and converts the polarization mode of the visible light from the TE0 mode to the TE1 mode. In the conversion portion 44, the asymmetric portion 49, the connecting portion 50, and the asymmetric portion 48 are arranged in that order from the end portion 45 toward the coupling portion 43. The connection end 44b is connected to the end portion 45, and the connection end 44a is connected to the coupling portion 43.

The coupling portion 43 is an optical waveguide for coupling the conversion portion 44 and the conversion portion 42. One end of the coupling portion 43 in the X-axis direction is connected to the connection end 44a, and the other end of the coupling portion 43 in the X-axis direction is connected to the connection end 42b. The red light in the TE1 mode is incident on the coupling portion 43 from the conversion portion 44. The coupling portion 43 transmits the red light while maintaining the polarization mode of the red light, and emits the red light in the TE1 mode to the conversion portion 42.

The conversion portion 42 is provided between the coupling portion 43 and the end portion 41, and converts the polarization mode of the visible light from the TE1 mode to the TM0 mode. The connection end 42b is connected to the coupling portion 43, and the connection end 42a is connected to the end portion 41. That is, the conversion region 42e and the conversion region 42d are arranged in that order from the coupling portion 43 toward the end portion 41.

The end portion 41 is positioned at the other end (emission end) of the mode converter 61R in the X-axis direction and functions as an emission portion. The red light in the TM0 mode is incident on the end portion 41 from the conversion portion 42. The end portion 41 transmits the red light while maintaining the polarization mode of the red light, and emits the red light in the TM0 mode to the modulator 62R (first modulator).

The modulator 62R is a modulator that modulates the light intensity of the red light. The modulator 62R is provided subsequent to the mode converter 61R, and modulates the light intensity of the red light in the TM0 mode emitted from the mode converter 61R. The modulator 62G (second modulator) is a modulator that modulates the light intensity of the green light. The modulator 62G is provided subsequent to the mode converter 61G, and modulates the light intensity of the green light in the TM0 mode emitted from the mode converter 61G. The modulator 62B (third modulator) is a modulator that modulates the light intensity of the blue light. The modulator 62B is provided subsequent to the mode converter 61B, and modulates the light intensity of the blue light in the TM0 mode emitted from the mode converter 61B.

The modulators 62R, 62G, and 62B are mainly different from the modulators 35R, 35G, and 35B in that they include the signal electrode 57B and the ground electrode 58B instead of the signal electrode 57, the ground electrode 58, and the ground electrode 59.

The signal electrode 57B is provided along the branch waveguide 53, above the branch waveguide 53 via a buffer layer (not shown). The ground electrode 58B is provided along the branch waveguide 54, above the branch waveguide 54 via a buffer layer (not shown). The cladding layer 33 does not cover a part of the signal electrode 57B and a part of the ground electrode 58B, and a part of the upper surface of the signal electrode 57B and a part of the upper surface of the ground electrode 58B are exposed. One end of the signal source SS is electrically connected to one end of the signal electrode 57B, and the other end of the signal source SS is electrically connected to one end of the ground electrode 58B. One end of the termination resistor TR is electrically connected to the other end of the signal electrode 57B, and the other end of the termination resistor TR is electrically connected to the other end of the ground electrode 58B.

Also, in the laser module 13B, the same effects as those of the laser module 13 can be obtained in the configuration common to the laser module 13. Also, in the optical element 30B, the same effects as those of the optical element 30 can be obtained in the configuration common to the optical element 30. In the laser module 13B and the optical element 30B, the visible light incident in the TE0 mode can be emitted in the TM0 mode. That is, the polarization mode of the visible light can be converted from the TE0 mode to the TM0 mode.

In the conversion portion 44 of the present embodiment, the asymmetric portion 49, the connecting portion 50, and the asymmetric portion 48 are arranged in that order in the X-axis direction, so that the conversion portion 44 has asymmetry in the Y-axis direction. When the red light in the TE0 mode is incident on the connection end 44b, the red light in the TE0 mode propagates in two effective optical path lengths different from each other, and phase changes different from each other occur in the two components. Since the width W1, the width W2, the width W3, the length L21, the length L22, and the length L23 are set so that the phase matching condition under which the two components are in opposite phases is satisfied, the red light in the TE1 mode is output from the connection end 44a. As described above, the polarization mode of the visible light can be converted from the TE0 mode to the TE1 mode.

In the conversion portion 42 of the present embodiment, the effective refractive index of the TM0 mode and the effective refractive index of the TE1 mode become closer to each other as the distance from the connection end 42b increases in the X-axis direction, so that conversion between the TM0 mode and the TE1 mode is induced. Accordingly, when the red light in the TE1 mode is incident on the connection end 42b, the polarization mode of the red light is converted from the TE1 mode to the TM0 mode in the conversion portion 42, and the red light in the TM0 mode is output from the connection end 42a. As described above, the polarization mode of the visible light can be converted from the TE1 mode to the TM0 mode.

In the laser module 13B and the optical element 30B, the core layer 32 is made of Z-cut lithium niobate, and the C-axis of the lithium niobate extends in the Z-axis direction. On the other hand, since the red laser diode 21B emits the red light in the TE0 mode, the green laser diode 22B emits the green light in the TE0 mode, and the blue laser diode 23B emits the blue light in the TE0 mode, the direction of the main electric field of each light is orthogonal to the C-axis direction of the lithium niobate constituting the core layer 32. On the other hand, the mode converters 61R, 61G, and 61B convert the polarization modes of the red, green, and blue light from the TE0 mode to the TM0 mode, respectively. Accordingly, the directions of the main electric fields of the respective lights are aligned with the C-axis direction, so that the modulation efficiencies in the modulators 62R, 62G, and 62B can be improved.

Further, in the laser module 13B and the optical element 30B, since the core layer 32 is made of Z-cut lithium niobate, the multiplexer 36 is designed so that the multiplexing efficiency in the case of multiplexing the red light, the green light, and the blue light in the TM0 mode is higher than the multiplexing efficiency in the case of multiplexing the red light, the green light, and the blue light in the TE0 mode. Accordingly, the multiplexing efficiency in the multiplexer 36 can be improved.

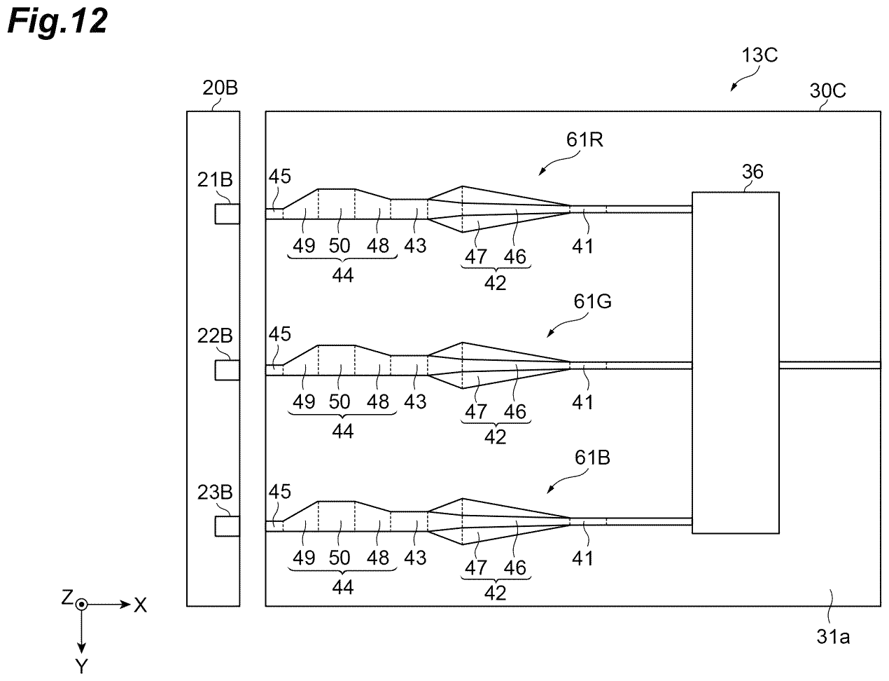

Next, a laser module including an optical element according to still another embodiment will be described with reference to FIG. 12. FIG. 12 is a plan view of a laser module including an optical element according to still another embodiment. In FIG. 12, the illustration of the cladding layer 33 is omitted for convenience of explanation. A laser module 13C shown in FIG. 12 is mainly different from the laser module 13B in that the laser module 13C includes an optical element 30C instead of the optical element 30B. The optical element 30C is mainly different from the optical element 30B in that the optical element 30C does not include the modulators 62R, 62G, and 62B.

Also, in the laser module 13C, the same effects as those of the laser module 13B can be obtained in the configuration common to the laser module 13B. Also, in the optical element 30C, the same effects as those of the optical element 30B can be obtained in the configuration common to the optical element 30B. Since the laser module 13C and the optical element 30C do not include the modulators 62R, 62G, and 62B, the laser module 13C and the optical element 30C can be reduced in size.

The optical element and the laser module according to the present disclosure are not limited to the above-described embodiments.

For example, each of the laser modules 13, 13A, 13B, and 13C may be applied to devices other than the near-eye wearable device 1.

The optical elements 30, 30A, 30B, and 30C are not required to include the cladding layer 33. In this case, the air layer can function as the upper cladding layer.

The optical elements 30, 30A, 30B, and 30C only need to include one mode converter. In other words, the core layer 32 only needs to include one mode converter for converting the polarization mode of the visible light between the TM0 mode and the TE0 mode.

The mode converters 34R, 34G, 34B, 61R, 61G, and 61B are not required to include the coupling portion 43. In this case, the connection end 42b is connected to the connection end 44a. According to this configuration, the lengths of the mode converters 34R, 34G, 34B, 61R, 61G, and 61B in the X-axis direction can be reduced. Accordingly, the laser module 13, 13A, 13B, and 13C, and the optical elements 30, 30A, 30B, and 30C can be reduced in size.

### EXAMPLES

Hereinafter, the present disclosure will be described in more detail with reference to Examples in order to explain the above effects. The present disclosure is not limited to these examples.

### <Evaluation of Conversion Loss in Conversion Portion 42>

The conversion losses in the conversion portions 42 having the structures of Examples 1 to 12 and Comparative Examples 1 and 2 were calculated. In Examples 1 to 12, a structure in which the upper tapered portion 46 and the lower tapered portion 47 shown in FIG. 5 were laminated was used. As shown in Table 1, the width W0, the width Wt, the width Ws, the width W1, the length L11, and the length L12 were set for each color wavelength. In Comparative Examples 1 and 2, a structure including only the upper tapered portion 46 shown in FIG. 5 was used. As shown in Table 1, in Comparative Examples 1 and 2, the width W0, the width Wt (=width Ws), the width W1, and the length L1 were set for the red wavelength. In Examples 1 to 12, the height T11 was set to 0.5 μm and the height T12 was set to 0.2 μm. In Comparative Examples 1 and 2, the height T0 was set to 0.7 μm. Table 1 shows the calculation results of the conversion loss.

TABLE 1

| | Wavelength | | W0 | Wt | Ws | W1 | L1 | L11 | L12 | Loss |
|---|---|---|---|---|---|---|---|---|---|---|
| | Color | nm | μm | μm | μm | μm | μm | μm | μm | dB |
| Example 1 | R | 637 | 0.45 | 0.80 | 3.0 | 0.85 | 560 | 500 | 60 | 1.1 |
| Example 2 | R | 637 | 0.45 | 0.80 | 3.0 | 0.85 | 670 | 600 | 70 | 1.0 |
| Example 3 | R | 637 | 0.45 | 0.80 | 3.0 | 0.85 | 810 | 800 | 10 | 1.0 |
| Example 4 | R | 637 | 0.45 | 0.80 | 3.0 | 0.85 | 1010 | 1000 | 10 | 1.0 |
| Example 5 | G | 520 | 0.45 | 0.80 | 2.0 | 0.85 | 460 | 400 | 60 | 1.7 |
| Example 6 | B | 455 | 0.45 | 0.55 | 1.3 | 0.85 | 450 | 400 | 50 | 1.7 |
| Example 7 | B | 455 | 0.45 | 0.55 | 1.3 | 0.85 | 430 | 350 | 80 | 1.7 |
| Example 8 | B | 455 | 0.45 | 0.55 | 1.3 | 0.85 | 360 | 350 | 10 | 1.7 |
| Example 9 | R | 637 | 0.45 | 1.00 | 3.0 | 0.85 | 560 | 500 | 60 | 1.1 |
| Example 10 | B | 455 | 0.45 | 0.50 | 1.3 | 0.85 | 360 | 350 | 10 | 1.7 |
| Example 11 | R | 637 | 0.45 | 0.80 | 5.0 | 0.85 | 560 | 500 | 60 | 1.1 |
| Example 12 | B | 455 | 0.45 | 0.55 | 1.0 | 0.85 | 360 | 350 | 10 | 1.7 |
| Comparative | R | 637 | 0.45 | 0.80 | 0.8 | 0.85 | 560 | — | — | 10< |
| Example 1 | | | | | | | | | | |
| Comparative | R | 637 | 0.45 | 3.00 | 3.0 | 0.85 | 560 | — | — | 10< |
| Example 2 | | | | | | | | | | |

In Examples 1 to 12, a relatively small loss of about 1.0 dB to 1.7 dB occurred. In Comparative Examples 1 and 2, a loss larger than 10 dB occurred. From these, it can be understood that in the conversion portion 42, by having an asymmetric structure in the Z-axis direction where the upper tapered portion 46 and the lower tapered portion 47 are stacked in the Z-axis direction, the conversion loss is reduced and the conversion efficiency is improved. In Examples 1 to 12, the length L1 was in the range of 360 μm or more and 1010 μm or less, the width Wt was in the range of 0.5 μm or more and 1.0 μm or less, and the width Ws was in the range of 1.0 μm or more and 5.0 μm or less. In this case, it can be understood that the conversion efficiency is improved.

### <Evaluation of Loss in Conversion Portion 44>

The conversion losses in the conversion portions 44 having the structures of Examples 13 to 17 and Comparative Example 3 were calculated. In Examples 13 to 17, a structure in which the asymmetric portion 48, the connecting portion 50, and the asymmetric portion 49 shown in FIG. 7 were arranged in the X-axis direction was used. In Comparative Example 3, a structure in which only the asymmetric portion 48 and the asymmetric portion 49 shown in FIG. 7 were arranged in the X-axis direction and the connecting portion 50 was not included was used. As shown in Table 2, the width W1, the width W2, the width W3, the length L21, the length L22, and the length L23 were set for each color wavelength. In Examples 13 to 17 and Comparative Example 3, the height T0 was set to 0.7 μm. Table 2 shows the calculation results of the conversion loss.

TABLE 2

| | Wavelength | | W1 | W2 | W3 | L2 | L21 | L22 | L23 | Loss |
|---|---|---|---|---|---|---|---|---|---|---|
| | Color | nm | μm | μm | μm | μm | μm | μm | μm | dB |
| Example 13 | R | 637 | 0.85 | 1.2 | 0.4 | 46 | 15 | 16 | 15 | 1.0 |
| Example 14 | G | 520 | 0.85 | 1.2 | 0.4 | 91 | 33 | 25 | 33 | 0.6 |
| Example 15 | B | 455 | 0.85 | 1.2 | 0.4 | 67 | 23 | 21 | 23 | 0.9 |
| Example 16 | G | 520 | 0.85 | 1.2 | 0.4 | 100 | 37 | 26 | 37 | 0.6 |
| Example 17 | R | 637 | 0.85 | 1.2 | 0.4 | 40 | 13 | 14 | 13 | 1.0 |
| Comparative | R | 637 | 0.85 | 1.2 | 0.4 | 30 | 15 | 0 | 15 | 10< |
| Example 3 | | | | | | | | | | |

In Examples 13 to 17, a relatively small loss of about 0.6 dB to 1.0 dB occurred. In Comparative Example 3, a loss larger than 10 dB occurred. From these, it can be understood that in the conversion portion 44, by having an asymmetric structure in the Y-axis direction where the asymmetric portion 48, the connecting portion 50, and the asymmetric portion 49 are arranged in the X-axis direction, the conversion loss is reduced and the conversion efficiency is improved. In Examples 13 to 17, the length L2 was in the range of 40 μm or more and 100 μm or less, and the width of the conversion portion 44 was in the range of 0.4 μm or more and 1.2 μm or less. In this case, it can be understood that the conversion efficiency is improved.

### Additional Statements

### [Clause 1]

An optical element comprising:
a substrate including a main surface; and
a core layer provided on the main surface and made of a material having an electro-optic effect,
wherein the core layer comprises a mode converter extending in a first direction along the main surface, the mode converter configured to convert a polarization mode of visible light between a TM0 mode and a TE0 mode,
wherein the mode converter comprises:
an incident portion positioned at one end of the mode converter in the first direction and on which the visible light in a first polarization mode which is one polarization mode among the TM0 mode and the TE0 mode is incident;
an emission portion positioned at another end of the mode converter in the first direction, the emission portion configured to emit the visible light in a second polarization mode which is another polarization mode among the TM0 mode and the TE0 mode;
a first conversion portion provided between the incident portion and the emission portion, the first conversion portion configured to convert the polarization mode of the visible light between the TM0 mode and a TE1 mode; and
a second conversion portion provided between the incident portion and the emission portion, the second conversion portion configured to convert the polarization mode of the visible light between the TE0 mode and the TE1 mode,
wherein the first conversion portion comprises a first end and a second end which are both ends in the first direction, and an upper tapered portion and a lower tapered portion which are stacked in a second direction intersecting the main surface,
wherein in a first region of the first conversion portion from the first end to an intermediate position between the first end and the second end, a length of the upper tapered portion in a third direction intersecting the first direction and the second direction continuously increases from a first length at the first end to a second length, which is longer than the first length, toward the intermediate position,
wherein in the first region, a length of the lower tapered portion in the third direction continuously increases from the first length at the first end to a third length, which is longer than the second length, toward the intermediate position,
wherein in a second region of the first conversion portion from the intermediate position to the second end, a length of the upper tapered portion in the third direction continuously increases from the second length at the intermediate position to a fourth length, which is longer than the second length and shorter than the third length, toward the second end, and
wherein in the second region, a length of the lower tapered portion in the third direction continuously decreases from the third length at the intermediate position to the fourth length toward the second end.

### [Clause 2]

The optical element according to clause 1,
wherein the first polarization mode is the TM0 mode and the second polarization mode is the TE0 mode, and
wherein the first end is connected to the incident portion, and the second conversion portion is provided between the first conversion portion and the emission portion.

### [Clause 3]

The optical element according to clause 1,
wherein the first polarization mode is the TE0 mode and the second polarization mode is the TM0 mode, and
wherein the first end is connected to the emission portion, and the second conversion portion is provided between the incident portion and the first conversion portion.

### [Clause 4]

The optical element according to any one of clauses 1 to 3,
wherein a length of the first conversion portion in the first direction is 360 μm or more and 1010 μm or less,
wherein the second length is 0.5 μm or more and 1.0 μm or less, and
wherein the third length is 1.0 μm or more and 5.0 μm or less.

### [Clause 5]

The optical element according to any one of clauses 1 to 4,
wherein the second conversion portion comprises:
a first asymmetric portion having an asymmetric shape in the third direction, with a length in the third direction continuously increasing from a fifth length to a sixth length, which is longer than the fifth length, as a distance from the first conversion portion increases;
a second asymmetric portion having an asymmetric shape in the third direction, with a length in the third direction continuously decreasing from the sixth length to a seventh length, which is shorter than the sixth length, as a distance from the first conversion portion increases; and
a connecting portion provided between the first asymmetric portion and the second asymmetric portion, with a length in the third direction being the sixth length over an entire length in the first direction.

### [Clause 6]

The optical element according to clause 5,
wherein a length of the second conversion portion in the first direction is 40 μm or more and 100 μm or less, and a length of the second conversion portion in the third direction is 0.4 μm or more and 1.2 μm or less.

### [Clause 7]

The optical element according to any one of clauses 1 to 6,
wherein the mode converter further comprises a coupling portion coupling the first conversion portion and the second conversion portion.

### [Clause 8]

The optical element according to clause 7,
wherein a length of the coupling portion in the third direction is constant over an entire length of the coupling portion in the first direction.

### [Clause 9]

The optical element according to any one of clauses 1 to 8,
wherein the core layer further comprises:
a first mode converter which is the mode converter configured to convert a polarization mode of red light from the first polarization mode to the second polarization mode;
a second mode converter which is the mode converter configured to convert a polarization mode of green light from the first polarization mode to the second polarization mode;
a third mode converter which is the mode converter configured to convert a polarization mode of blue light from the first polarization mode to the second polarization mode; and
a multiplexer configured to multiplex the red light, the green light, and the blue light to emit laser light.

### [Clause 10]

The optical element according to clause 9,
wherein the core layer further comprises:
a first modulator configured to modulate light intensity of the red light;
a second modulator configured to modulate light intensity of the green light; and
a third modulator configured to modulate light intensity of the blue light.

### [Clause 11]

A laser module comprising:
the optical element according to clause 9 or 10;
a first light source configured to emit the red light in the first polarization mode;
a second light source configured to emit the green light in the first polarization mode; and
a third light source configured to emit the blue light in the first

What is claimed is:

1. An optical element comprising:
a substrate including a main surface; and
a core layer provided on the main surface and made of a material having an electro-optic effect,
wherein the core layer comprises a mode converter extending in a first direction along the main surface, the mode converter configured to convert a polarization mode of visible light between a TM0 mode and a TE0 mode,
wherein the mode converter comprises:
an incident portion positioned at one end of the mode converter in the first direction and on which the visible light in a first polarization mode which is one polarization mode among the TM0 mode and the TE0 mode is incident;
an emission portion positioned at another end of the mode converter in the first direction, the emission portion configured to emit the visible light in a second polarization mode which is another polarization mode among the TM0 mode and the TE0 mode;
a first conversion portion provided between the incident portion and the emission portion, the first conversion portion configured to convert the polarization mode of the visible light between the TM0 mode and a TE1 mode; and
a second conversion portion provided between the incident portion and the emission portion, the second conversion portion configured to convert the polarization mode of the visible light between the TE0 mode and the TE1 mode,
wherein the first conversion portion comprises a first end and a second end which are both ends in the first direction, and an upper tapered portion and a lower tapered portion which are stacked in a second direction intersecting the main surface,
wherein in a first region of the first conversion portion from the first end to an intermediate position between the first end and the second end, a length of the upper tapered portion in a third direction intersecting the first direction and the second direction continuously increases from a first length at the first end to a second length, which is longer than the first length, toward the intermediate position,
wherein in the first region, a length of the lower tapered portion in the third direction continuously increases from the first length at the first end to a third length, which is longer than the second length, toward the intermediate position,
wherein in a second region of the first conversion portion from the intermediate position to the second end, a length of the upper tapered portion in the third direction continuously increases from the second length at the intermediate position to a fourth length, which is longer than the second length and shorter than the third length, toward the second end, and
wherein in the second region, a length of the lower tapered portion in the third direction continuously decreases from the third length at the intermediate position to the fourth length toward the second end.

2. The optical element according to claim 1,
wherein the first polarization mode is the TM0 mode and the second polarization mode is the TE0 mode, and
wherein the first end is connected to the incident portion, and the second conversion portion is provided between the first conversion portion and the emission portion.

3. The optical element according to claim 1,
wherein the first polarization mode is the TE0 mode and the second polarization mode is the TM0 mode, and
wherein the first end is connected to the emission portion, and the second conversion portion is provided between the incident portion and the first conversion portion.

4. The optical element according to claim 1,
wherein a length of the first conversion portion in the first direction is 360 μm or more and 1010 μm or less,
wherein the second length is 0.5 μm or more and 1.0 μm or less, and
wherein the third length is 1.0 μm or more and 5.0 μm or less.

5. The optical element according to claim 1,
wherein the second conversion portion comprises:
a first asymmetric portion having an asymmetric shape in the third direction, with a length in the third direction continuously increasing from a fifth length to a sixth length, which is longer than the fifth length, as a distance from the first conversion portion increases;
a second asymmetric portion having an asymmetric shape in the third direction, with a length in the third direction continuously decreasing from the sixth length to a seventh length, which is shorter than the sixth length, as a distance from the first conversion portion increases; and
a connecting portion provided between the first asymmetric portion and the second asymmetric portion, with a length in the third direction being the sixth length over an entire length in the first direction.

6. The optical element according to claim 5,
wherein a length of the second conversion portion in the first direction is 40 μm or more and 100 μm or less, and a length of the second conversion portion in the third direction is 0.4 μm or more and 1.2 μm or less.

7. The optical element according to claim 1,
wherein the mode converter further comprises a coupling portion coupling the first conversion portion and the second conversion portion.

8. The optical element according to claim 7,
wherein a length of the coupling portion in the third direction is constant over an entire length of the coupling portion in the first direction.

9. The optical element according to claim 1,
wherein the core layer further comprises:
a first mode converter which is the mode converter configured to convert a polarization mode of red light from the first polarization mode to the second polarization mode;
a second mode converter which is the mode converter configured to convert a polarization mode of green light from the first polarization mode to the second polarization mode;
a third mode converter which is the mode converter configured to convert a polarization mode of blue light from the first polarization mode to the second polarization mode; and
a multiplexer configured to multiplex the red light, the green light, and the blue light to emit laser light.

10. The optical element according to claim 9,
wherein the core layer further comprises:
a first modulator configured to modulate light intensity of the red light;
a second modulator configured to modulate light intensity of the green light; and
a third modulator configured to modulate light intensity of the blue light.

11. A laser module comprising:
the optical element according to claim 9;
a first light source configured to emit the red light in the first polarization mode;
a second light source configured to emit the green light in the first polarization mode; and
a third light source configured to emit the blue light in the first polarization mode.

12. A laser module comprising:
the optical element according to claim 10;
a first light source configured to emit the red light in the first polarization mode;
a second light source configured to emit the green light in the first polarization mode; and
a third light source configured to emit the blue light in the first polarization mode.
